(19) United States
(12) Patent Application Publication
(10) Pub. No.: US 2026/0062792 A1
(43) Pub. Date: Mar. 5, 2026

(54) HIGH ASPECT RATIO GAP FILL USING CYCLIC DEPOSITION AND ETCH

(71) Applicant: Applied Materials, Inc., Santa Clara, CA (US)

(72) Inventors: Alexia Adilene PORTILLO RIVERA, Sunnyvale, CA (US); Takashi KURATOMI, San Jose, CA (US)

(21) Appl. No.: 19/104,809

(22) PCT Filed: Aug. 25, 2023
(86) PCT No.: PCT/US2023/031175

§ 371 Date: Feb. 19, 2025

Related U.S. Application Data
(60) Provisional application No. 63/373,662, filed on Aug. 26, 2022.

(51) Int. Cl. C23C 14/08; C23C 14/04; C23C 14/58

(52) U.S. Cl. CPC C23C 14/083; C23C 14/046; C23C 14/5826

(57) ABSTRACT

Embodiment of the present disclosure generally relate to optical device structures and methods for forming a metal containing interconnection structure in a high aspect ratio gap on a substrate for an optical device. In one embodiment, the method includes providing a substrate having a gap in a material layer disposed on a substrate, depositing a gap fill material in an opening of the gap, etching the gap fill material to remove portions of the gap fill material deposited in the gap, and cyclically depositing more of the gap fill material in the opening of the gap to completely fill the gap.

### BACKGROUND

### Field

Embodiments of the present disclosure generally relate to display devices for augmented, virtual, and mixed reality. More specifically, embodiments described herein provide a method for forming an optical component for a display device.

### Description of the Related Art

Virtual reality is generally considered to be a computer generated simulated environment in which a user has an apparent physical presence. A virtual reality experience can be generated in 3D and viewed with a head-mounted display (HMD), such as glasses or other wearable display devices that have near-eye display panels as lenses to display a virtual reality environment that replaces an actual environment.

Augmented reality enables an experience in which a user can still see through the display lenses of the glasses or other HMD device to view the surrounding environment, yet also see images of virtual objects that are generated for display and appear as part of the environment. Augmented reality can include any type of input, such as audio and haptic inputs, as well as virtual images, graphics, and video that enhances or augments the environment that the user experiences.

Both virtual reality and augmented reality display devices utilize optical components, such as waveguides or flat lens/meta surfaces, including micro or nano structures with contrasting refractive index (RI). Conventionally, in fabricating such optical components, three dimensional (3D) stacking of integrated circuit components is often utilized to improve performance of transistors. By arranging transistors in three dimensions instead of two dimensions, multiple transistors may be placed in the integrated circuits (ICs) very close to each other. Three dimensional (3D) stacking of semiconductor chips reduces wire lengths and keeps wiring delay low. As the width of trenches continues to shrink, the aspect ratio (depth divided by width) continues to grow with the stacking of the integrated circuit components. One challenge regarding the manufacture of high aspect ratio trenches is avoiding the formation of voids during the deposition of desired materials in the trenches.

To fill a trench, a layer of material layer, such as dielectric layer or metal layer, is deposited into the trench. The material layer typically covers the field, as well as the walls and the bottom of the trench. In general, a physical vapor deposition (PVD) process can only completely fill wide and shallow trenches with minimal defects, such as trenches with aspect ratios of 0.4:1 or less. Moreover, increasing bias power generally only improves coverage on the bottom surface of the trench, but does enable the trench to be completely filled. Instead, when PVD is used to gap fill trenches with higher aspect ratio, the opening of the trench becomes more likely to “pinch off” during the deposition process before the trench is completely filled, thereby forming a void (e.g., defects) within the trench.

Thus, a need exists for improvements in methods for forming material layers in high aspect ratio trenches.

### SUMMARY

In one embodiment, a method for forming an optical device structure is disclosed. The method includes providing a substrate having a gap in a material layer disposed over a top surface of the substrate. The gap may include trenches, vias, holes, apertures and the like formed in the material layer on the substrate for an optical device. The method continues with depositing a gap fill material over the material layer and in an opening of the gap in the material layer, and etching the gap fill material to remove portions of the gap fill material deposited in the gap. The method may optionally include performing an O₂ plasma treatment process on a top surface of the gap fill material to re-oxidize the top surface of the gap fill material after portions of the gap fill material is etched. The method concludes with depositing more of the gap fill material in the opening of the gap to completely fill the gap.

In another embodiment, a method for forming an optical device structure using a cluster processing system is provided. The method includes disposing a substrate having a gap in a material layer disposed over the substrate into a first process chamber of the cluster processing system and performing a deposition process using the first process chamber to deposit a gap fill material in an opening of the gap in the material layer. The method further includes transferring the substrate from the first process chamber to a second process chamber of the cluster processing system and performing an etch process using the second process chamber to remove portions of the gap fill material deposited in the gap on the substrate. The method may include cyclically transferring the substrate between the first and second process chambers to cyclically repeat the depositing process and the etch process to incrementally fill the gap in the material layer with the gap fill material. The method concludes with transferring the substrate to the first process chamber of the cluster processing system and performing a final deposition process to deposit more of the gap fill material in the opening of the gap to completely fill the gap.

In further embodiments, a method for forming an optical device structure is provided. The method includes providing a substrate having a gap in a material layer disposed over a top surface of the substrate and performing a vapor deposition process to deposit a gap fill material over the material layer and in an opening of the gap in the material layer. The method continues with performing a sputtering etch process to remove portions of the gap fill material deposited in the gap and near the opening of the gap and repeating performances of the vapor deposition process and the sputtering etch process to incrementally fill the gap with the gap fill material. The method then continues with performing a final vapor deposition process to deposit more of the gap fill material in the opening of the gap to completely fill the gap.

In another embodiment, an optical device structure is provided. The optical device structure includes a material layer disposed over a substrate, the material layer having a gap formed therein extending from a top surface of the material layer towards the substrate. The optical device structure also includes a gap fill material disposed over the material layer and in the gap. The gap fill material completely fills the gap in the material layer to form an interconnection structure, wherein the interconnection structure is formed by depositing the gap fill material over the material layer and in the gap to partially fill the gap, etching the gap fill material to remove portions of the gap fill material deposited in the gap, continuing to cyclically deposit more of the gap fill material in the gap and etch portions of the gap fill material deposited in the gap to incrementally fill the gap with the gap fill material, and depositing more of the gap fill material in the gap to completely fill the gap.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 depicts an embodiment of a process chamber that may be utilized to perform a physical vapor deposition (PVD) processing on a substrate, according to one embodiment of the present disclosure;

FIG. 2 depicts an embodiment of a pre-clean process chamber which may be utilized to perform an etching process on a substrate, according to one embodiment of the present disclosure;

FIG. 3 depicts an embodiment of a cluster processing system that may have the process chambers from FIGS. 1 and 2 incorporated thereto, according to one embodiment of the present disclosure;

FIG. 4 depicts a flow diagram of an embodiment of a method for forming a metal containing structure on a substrate, according to one embodiment of the present disclosure;

FIG. 5 depicts a schematic cross-sectional view of an embodiment of an interconnection structure on a substrate formed by the methods of FIGS. 4 and 6, according to certain embodiments of the present disclosure;

FIG. 6 depicts a flow diagram of an embodiment of a method for forming a metal containing material on a substrate using the cluster processing system depicted in FIG. 3, according to one embodiment of the present disclosure;

FIG. 7 depicts a schematic cross-sectional view of an embodiment of an interconnection structure on a substrate manufactured by the method of FIGS. 4 and 6, according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to systems and methods for forming a metal containing interconnection structure on a substrate with complete gap filling performance in a high aspect ratio gap (typically at least 0.6:1). Generally, deposition process methods for gap fill either deposit more material on the upper region of a sidewall or form cusps that “pinch” at the entry of the gap. To remove sidewall and entry deposits and to keep the gap open for further deposition to completely fill the gap without void and seam formations, a method including a multi-cycle deposition and etch process is disclosed herein. In an embodiment, the method disclosed includes performing multiple cycles wherein each cycle includes a deposition process to form a layer of a gap fill material followed by an etching process to erode portions of the deposited layer including excess buildups on the sidewall or entry of the trench.

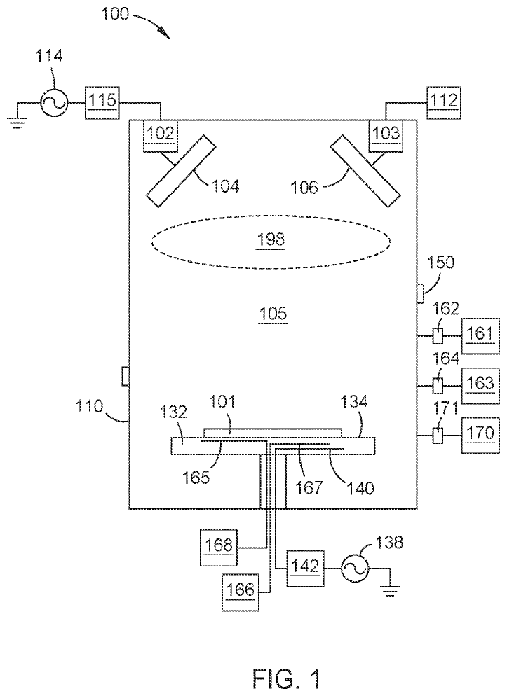

FIG. 1 is a schematic cross-sectional view of a process chamber 100 according to one embodiment described herein. The process chamber 100 may be a deposition chamber, such as a physical vapor deposition (PVD) process chamber. The process chamber 100 may be used to perform the methods described herein and configured at least to deposit a thin film on a substrate 101. It is to be understood that the process chamber 100 is an exemplary PVD chamber and other PVD chambers, including PVD chambers from other manufacturers, may be used with or modified to accomplish the methods of the present disclosure. While PVD is discussed in this disclosure, various deposition techniques, such as chemical vapor deposition (CVD), plasma enhanced chemical vapor deposition (PECVD), atomic layer deposition (ALD), plasma enhanced atomic layer deposition (PEALD), low pressure chemical vapor deposition (LPCVD), etc., are also contemplated.

The process chamber 100 includes one or more cathodes 102, 103 that have a corresponding single target or a plurality of targets, attached to the chamber body 110 (e.g., via a chamber body adapter). In the implementation shown in FIG. 1, the process chamber 100 includes at least one first target 104 and at least one second target 106. The first target 104 includes at least one first material described herein and the second target 106 includes at least one second material described herein. Each cathode (e.g., the first target 104 and second target 106) may be coupled to a DC power source 112 and/or an RF power source 114 and matching network 115.

The process chamber 100 is configured to include a substrate support 132 having a support surface 134 to support the substrate 101. The process chamber 100 includes an opening 150 (e.g., a slit valve) through which an end effector (not shown) extends to place a substrate 101 onto lift pins (not shown) for lowering the substrate 101 onto the support surface 134.

The process chamber 100 includes a sputter gas source 161 operable to supply a sputter gas to a process volume 105. A plasma 198 can be generated in the processing volume 105 from a non-reactive sputter gas (such as argon (Ar), krypton (Kr), etc., and/or from a process gas including an oxygen-containing gas (e.g., O₂) for oxide deposition or a nitrogen-containing gas (e.g., N₂) for nitride deposition, according to some embodiments. The present disclosure contemplates that other sputter gas(es) may also be used.

A gas flow controller 162 is disposed between the sputter gas source 161 and the process volume 105 to control a flow of the sputter gas from the sputter gas source 161 to the process volume 105. The process chamber 100 also includes a reactive gas source 163 operable to supply a reactive gas, such as an oxygen-containing gas or nitrogen-containing gas to the process volume 105. A gas flow controller 164 is disposed between the reactive gas source 163 and the process volume 105 to control a flow of the reactive gas from the reactive gas source 163 to the process volume 105. The process chamber 100 may include a precursor gas source 170 operable to supply a precursor gas to the process volume 105. In one embodiment, which can be combined with other embodiments, a gas flow controller 171 is disposed between the precursor gas source 170 and the process volume 105 to control a flow of the precursor gas from the precursor gas source 170 to the process volume 105. Sputter gases, reactive gases, and precursor gases may each be referred to as process gases herein. During processing, the process volume 105 can be maintained at a process pressure using a vacuum device and/or the gas flow controllers 162, 164, 171.

The substrate support 132 includes an RF bias power source 138 coupled to a bias electrode 140 disposed in the substrate support 132 via a matching network 142. The substrate support 132 includes a mechanism (not shown) that retains the substrate 101 on the support surface 134 of the substrate support 132, such as an electrostatic chuck, a vacuum chuck, a substrate retaining clamp, or the like. The substrate support 132 includes a cooling conduit 165 disposed in the substrate support 132 where the cooling conduit 165 controllably cools the substrate support 132 and the substrate 101 positioned thereon to a predetermined temperature, for example between about −20° C. to about 300° C. The cooling conduit 165 is coupled to a cooling fluid source 168 to provide cooling fluid (not shown). The substrate support 132 also includes a heater 167 embedded therein. The heater 167, such as a resistive element, disposed in the substrate support 132 is coupled to an optional heater power source 166 and controllably heats the substrate support 132 and the substrate 101 positioned thereon to a predetermined temperature, for example between about −150° C. to about 500° C.

While FIG. 1 depicts one first target 104 and one second target 106, the process chamber 100 may include one or more first targets 104 and/or one or more second targets 106. For example, 3-5 targets selected from at least one of the first targets 104 and/or the second targets 106 may be included in the process chamber 100. Each first target 104 is operable to deposit a different material. For example, 3-5 second targets 106 may be included in the process chamber 100. Each second target 106 is operable to deposit a different material. In one or more embodiments with the one or more first targets 104 and the one or more second target 106, each first target 104 is operable to deposit a different first material and/or each second target 106 is operable to deposit a different second material on the substrate 101

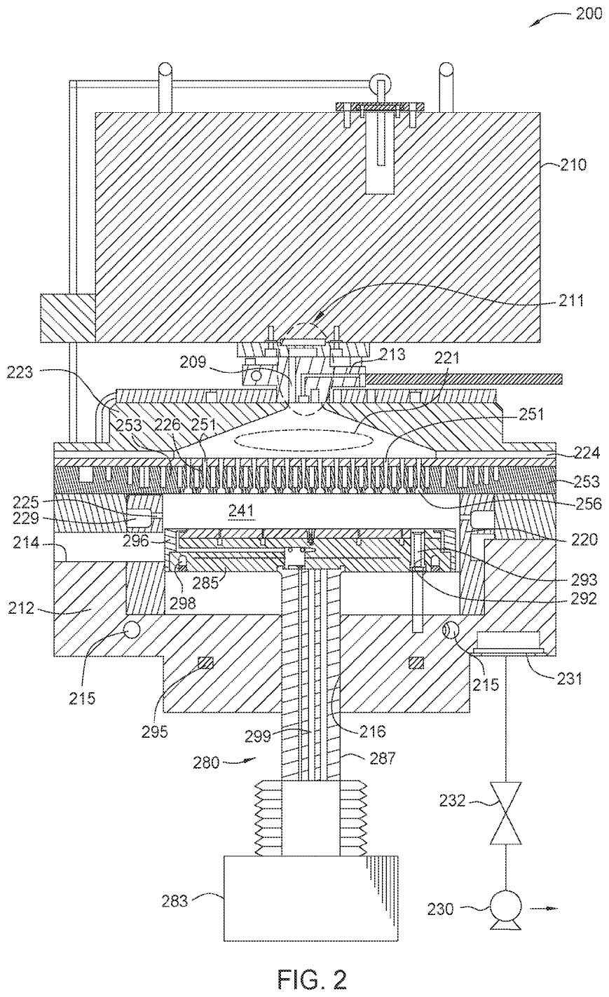

FIG. 2 is a schematic cross-sectional view of a process chamber 200 according to one embodiment described herein. The process chamber 200 may be an etching chamber, such as a pre-cleaning process chamber. The process chamber 200 may be configured to remove oxides or metal particles from a surface of the substrate 101. The process chamber 200 is particularly useful for performing a thermal or plasma-based cleaning process and/or a plasma assisted dry etch process. The process chamber 200 may be a Frontier™, PCxT Reactive Preclean™ (RPC), AKTIV Pre-Clean™, Siconi™ or Capa™ chamber, which is available from Applied Materials, Santa Clara, California. It is noted that other vacuum process chambers including those available from other manufactures may also be adapted to practice the present disclosure.

The process chamber 200 includes a chamber body 212, a lid assembly 223, and a support assembly 280. The lid assembly 223 is disposed at an upper end of the chamber body 212, and the support assembly 280 is at least partially disposed within the chamber body 212.

The chamber body 212 includes a slit valve opening 214 formed in a sidewall thereof to provide access to the interior of the process chamber 200. The slit valve opening 214 is selectively opened and closed to allow access to the interior of the chamber body 212 by a wafer handling robot (not shown).

In one or more implementations, the chamber body 212 includes a channel 215 formed therein for flowing a heat transfer fluid therethrough. The chamber body 212 can further include a liner 220 that surrounds the support assembly 280. The liner 220 is removable for servicing and cleaning. In one or more embodiments, the liner 220 includes one or more apertures 225 and a pumping channel 229 formed therein that is in fluid communication with a vacuum system. The apertures 225 provide a flow path for gases into the pumping channel 229, which provides an egress for the gases within the process chamber 200.

The vacuum system can include a vacuum pump 230 and a throttle valve 232 to regulate flow of gases through the process chamber 200. The vacuum pump 230 is coupled to a vacuum port 231 disposed in the chamber body 212 and therefore, in fluid communication with the pumping channel 229 formed within the liner 220.

A remote plasma system 210 may process a halogen containing precursor, for example oxygen-containing precursor, which then travels through a gas inlet assembly 211. Two distinct gas supply channels (a first channel 209 and a second channel 213) are visible within the gas inlet assembly 211. The first channel 209 carries a gas that passes through the remote plasma system 210 (RPS), while the second channel 213 bypasses the remote plasma system 210. The first channel 209 may be used for a process gas and the second channel 213 may be used for a treatment gas. In an embodiment, either the first or second channel 209, 213 may be used for a halogen-containing precursor.

A lid assembly 223 (or conductive top portion) and a perforated partition 253 (or a showerhead) are shown with an insulating ring 224 in between, which allows an AC potential to be applied to the lid assembly 223 relative to the perforated partition 253. The AC potential strikes a plasma in a chamber plasma region 221. The process gas may travel through the first channel 209 into the chamber plasma region 221 and may be excited by a plasma in the chamber plasma region 221 alone or in combination with the remote plasma system 210. If the process gas flows through the second channel 213, then only the chamber plasma region 221 is used for excitation. The combination of the chamber plasma region 221 and/or the remote plasma system 210 may be referred to as a remote plasma system herein.

The perforated partition 253 (also referred to as a showerhead) separates the chamber plasma region 221 from a substrate processing region 241 beneath the perforated partition 253. The perforated partition 253 allows a plasma present in the chamber plasma region 221 to avoid directly exciting gases in the substrate processing region 241, while still allowing excited species to travel from the chamber plasma region 221 into the substrate processing region 241. The perforated partition 253 is positioned between the chamber plasma region 221 and the substrate processing region 241 and allows plasma effluents (excited derivatives of precursors or other gases) created within remote plasma system 210 and/or the chamber plasma region 221 to pass through a plurality of through-holes 256. The perforated partition 253 also has one or more hollow volumes 251 which can be filled with a precursor in the form of a vapor or gas and pass through the through-holes 256 into the substrate processing region 241 but not directly into the chamber plasma region 221. In order to maintain a significant concentration of excited species penetrating from the chamber plasma region 221 to the substrate processing region 241, the length 226 of the through-holes 256 may be restricted and configured in different configurations as needed.

The perforated partition 253 may be configured to serve as an ion suppressor as shown in FIG. 2. Alternatively, a separate process chamber element may be included (not shown) which suppresses the ion concentration traveling into the substrate processing region 241. The lid assembly 223 and the perforated partition 253 may function as a first electrode and second electrode, respectively, so that the lid assembly 223 and the perforated partition 253 may receive different electric voltages. In these configurations, electrical power (e.g., RF power) may be applied to the lid assembly 223, the perforated partition 253, or both. For example, the electrical power may be applied to the lid assembly 223 while the perforated partition 253 (serving as ion suppressor) is grounded. The process chamber 200 may include a RF generator that provides the electrical power to the lid assembly 223 and/or the perforated partition 253 as needed. The voltage applied to the lid assembly 223 may facilitate a uniform distribution of plasma (i.e., reduce localized plasma) within the chamber plasma region 221. To enable the formation of a plasma in the chamber plasma region 221, the insulating ring 224 may electrically insulate the lid assembly 223 from the perforated partition 253. The insulating ring 224 may be made from a ceramic and may have a high breakdown voltage to avoid sparking. Portions of the process chamber 200 near the capacitively-coupled plasma components just described may further include a cooling unit (not shown) that includes one or more cooling fluid channels to cool surfaces exposed to the plasma with a circulating coolant (e.g., water).

In the embodiment shown, the perforated partition 253 may distribute (via through-holes 256) process gases which contain hydrogen, fluorine and/or plasma effluents of such process gases upon excitation by a plasma in the chamber plasma region 221. In embodiments, the process gas introduced into the remote plasma system 210 and/or the chamber plasma region 221 may contain oxygen (such as O₂) or fluorine (such as F₂ or HF). The process gas may also include a carrier gas such as helium, argon, hydrogen (H₂), etc.

The through-holes 256 are configured to suppress the migration of ionically-charged species out of the chamber plasma region 221 while allowing uncharged neutral or radical species to pass through the perforated partition 253 into the substrate processing region 241. These uncharged species may include highly reactive species that are transported with less-reactive carrier gas by the through-holes 256. As noted above, the migration of ionic species by the through-holes 256 may be reduced, and in some instances completely suppressed. Controlling the amount of ionic species passing through the perforated partition 253 provides increased control over the gas mixture brought into contact with the underlying wafer substrate, which in turn increases control of the deposition and/or etch characteristics of the gas mixture. For example, adjustments in the ion concentration of the gas mixture can significantly alter the etch selectivity.

In embodiments, the number of the through-holes 256 may be between about 60 and about 2800. The through-holes 256 may have a variety of shapes but are most easily made round. There is also latitude in choosing the cross-sectional shape of through-holes, which may be made conical, cylindrical or combinations of the two shapes. The through-holes 256 may be configured to control the passage of the plasma-activated gas (i.e., the ionic, radical, and/or neutral species) through the perforated partition 253. For example, the aspect ratio of the holes (i.e., the hole diameter to length) and/or the geometry of the holes may be controlled so that the flow of ionically-charged species in the activated gas passing through the perforated partition 253 is reduced. The through-holes 256 in the perforated partition 253 may include a tapered portion that faces the chamber plasma region 221, and a cylindrical portion that faces the substrate processing region 241. The cylindrical portion may be proportioned and dimensioned to control the flow of ionic species passing into the substrate processing region 241. An adjustable electrical bias may also be applied to the perforated partition 253 as an additional means to control the flow of ionic species through the perforated partition 253.

Alternatively, the through-holes 256 may have a smaller inner diameter (ID) toward the top surface of the perforated partition 253 and a larger ID toward the bottom surface. In addition, the bottom edge of the through-holes 256 may be chamfered to help evenly distribute the plasma effluents in the substrate processing region 241 as the plasma effluents exit the showerhead and promote even distribution of the plasma effluents and precursor gases. The smaller ID may be placed at a variety of locations along the through-holes 256 and still allow the perforated partition 253 to reduce the ion density within the substrate processing region 241. The reduction in ion density results from an increase in the number of collisions with walls prior to entry into the substrate processing region 241. Each collision increases the probability that an ion is neutralized by the acquisition or loss of an electron from the wall. Generally speaking, the smaller ID of the through-holes 256 may be between about 0.2 mm and about 20 mm. In other embodiments, the smaller ID may be between about 1 mm and 6 mm or between about 0.2 mm and about 5 mm. Further, aspect ratios of the through-holes 256 (i.e., the smaller ID to hole length) may be approximately 1 to 20. The smaller ID of the through-holes 256 may be the minimum ID found along the length of the through-holes. The cross sectional shape of through-holes 256 may be generally cylindrical, conical, or any combination thereof.

The support assembly 280 can include a support member 285 to support substrate (not shown in FIG. 2) for processing within the chamber body 212. The support member 285 can be coupled to a lift mechanism 283 through a shaft 287 which extends through a centrally-located opening 216 formed in a bottom surface of the chamber body 212. The lift mechanism 283 can be flexibly sealed to the chamber body 212 by a bellows 188 that prevents vacuum leakage from around the shaft 287.

The support member 285 can include bores 292 formed therethrough to accommodate lift pins 293, one of which is shown in FIG. 2. Each lift pin 293 is constructed of ceramic or ceramic-containing materials, and is used for handling and transport of substrate 101. The lift pin 293 is moveable within its respective bore 292 when engaging an annular lift ring 295 disposed within the chamber body 212. The support assembly 280 can further include an edge ring 296 disposed about the support member 285.

The temperature of the support assembly 280 can be controlled by a fluid circulated through a fluid channel 298 embedded in the body of the support member 285. In one or more implementations, the fluid channel 298 is in fluid communication with a heat transfer conduit 299 disposed through the shaft 287 of the support assembly 280. The fluid channel 298 is positioned about the support member 285 to provide a uniform heat transfer to the substrate receiving surface of the support member 285. The fluid channel 298 and heat transfer conduit 299 can flow heat transfer fluids to either heat or cool the support member 285. Any suitable heat transfer fluid may be used, such as water, nitrogen, ethylene glycol, or mixtures thereof. The support assembly 280 can further include an embedded thermocouple (not shown) for monitoring the temperature of the support surface of the support member 285. For example, a signal from the thermocouple may be used in a feedback loop to control the temperature or flow rate of the fluid circulated through the fluid channel 298.

The support member 285 can be moved vertically within the chamber body 212 so that a distance between support member 285 and the lid assembly 223 can be controlled. A sensor (not shown) can provide information concerning the position of support member 285 within process chamber 200.

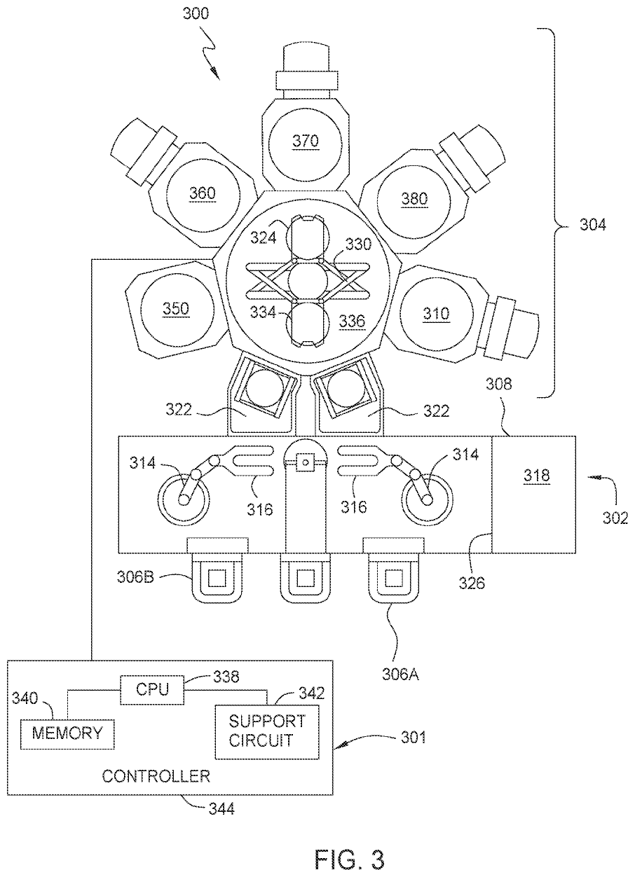

FIG. 3 is a schematic, top plan view of an exemplary cluster processing system 300 that includes one or more of the process chambers that are incorporated and integrated therein. The process chambers 100, 200 discussed above may be integrated in a cluster processing system, such as the cluster processing system 300 depicted in FIG. 3. In one embodiment, the cluster processing system 300 may be a CENTURA® or ENDURA® integrated processing system, commercially available from Applied Materials, Inc., located in Santa Clara, California. It is contemplated that other processing systems (including those from other manufacturers) may be adapted to benefit from the disclosure.

The cluster processing system 300 includes a vacuum-tight processing platform 304, a factory interface 302, and a system controller 344. The platform 304 includes a plurality of process chambers 350, 360, 370, 380 and at least one load lock chamber 322 that is coupled to a vacuum substrate transfer chamber 336. Two load lock chambers 322 are shown in FIG. 3. The factory interface 302 is coupled to the transfer chamber 336 by the load lock chambers 322.

In one embodiment, the factory interface 302 comprises at least one docking station 308 and at least one factory interface robot 314 to facilitate transfer of substrates. The docking station 308 is configured to accept one or more front opening unified pod (FOUP). Two FOUPS 306A, 306B are shown in the embodiment of FIG. 3. The factory interface robot 314 having a blade 316 disposed on one end of the factory interface robot 314 is configured to transfer a substrate from the factory interface 302 to the processing platform 304 for processing through the load lock chambers 322. Optionally, one or more metrology stations 318 may be connected to a terminal 326 of the factory interface 302 to facilitate measurement of the substrate from the FOUPS 306A, 306B.

Each of the load lock chambers 322 have a first port coupled to the factory interface 302 and a second port coupled to the transfer chamber 336. The load lock chambers 322 are coupled to a pressure control system (not shown) which pumps down and vents the load lock chambers 322 to facilitate passing the substrate between the vacuum environment of the transfer chamber 336 and the substantially ambient (e.g., atmospheric) environment of the factory interface 302.

The transfer chamber 336 has a vacuum robot 330 disposed therein. The vacuum robot 330 has a blade 334 capable of transferring substrates 324 among the load lock chambers 322, a metrology system 310 and the process chambers 350, 360, 370, 380.

In one embodiment of the cluster processing system 300, the cluster processing system 300 may include one or more process chambers 350, 360, 370, 380, which may be a deposition chamber (e.g., physical vapor deposition chamber, chemical vapor deposition, atomic layer deposition or other deposition chambers), annealing chamber (e.g., high pressure annealing chamber, RTP chamber, laser anneal chamber), etch chamber, cleaning chamber, pre-cleaning chamber, curing chamber, lithographic exposure chamber, or other similar type of semiconductor process chambers. In some embodiments of the cluster processing system 300, the system 300 includes one or more of process chambers 350, 360, 370, 380, the transfer chamber 336, the factory interface 302 and/or at least one of the load lock chambers 322.

The system controller 344 is coupled to the cluster processing system 300. The system controller 344, which may include the computing device 301 or be included within the computing device 301, controls the operation of the cluster processing system 300 using a direct control of the process chambers 350, 360, 370, 380 of the cluster processing system 300. Alternatively, the system controller 344 may control the computers (or controllers) associated with the process chambers 350, 360, 370, 380 and the cluster processing system 300. In operation, the system controller 344 also enables data collection and feedback from the respective chambers to optimize performance of the cluster processing system 300.

The system controller 344, much like the computing device 301 described above, generally includes a central processing unit (CPU) 338, a memory 340, and support circuits 342. The CPU 338 may be one of any form of a general purpose computer processor that can be used in an industrial setting. The support circuits 342 are conventionally coupled to the CPU 338 and may comprise cache, clock circuits, input/output subsystems, power supplies, and the like. The software routines transform the CPU 338 into a specific purpose computer (controller) 344. The software routines may also be stored and/or executed by a second controller (not shown) that is located remotely from the cluster processing system 300.

The process chambers 350, 360, 370, 380 may be outfitted to perform a variety of substrate processing operations similar to process chambers 100, 200 described herein. Any of the process chambers 350, 360, 370, 380 can be removed from the cluster processing system 300 if not necessary for a particular process to be performed by the cluster processing system 300. In an embodiment, the cluster processing system 300 may be configured to include the process chamber 100 and the process chamber 200 described herein. For example, the process chamber 350 can be configured as a physical vapor deposition chamber, and the process chamber 360 can be configured as a pre-cleaning chamber.

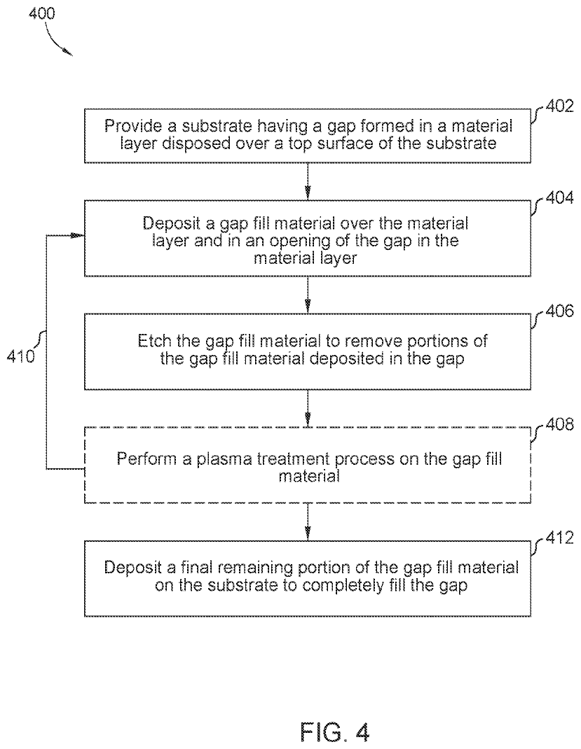

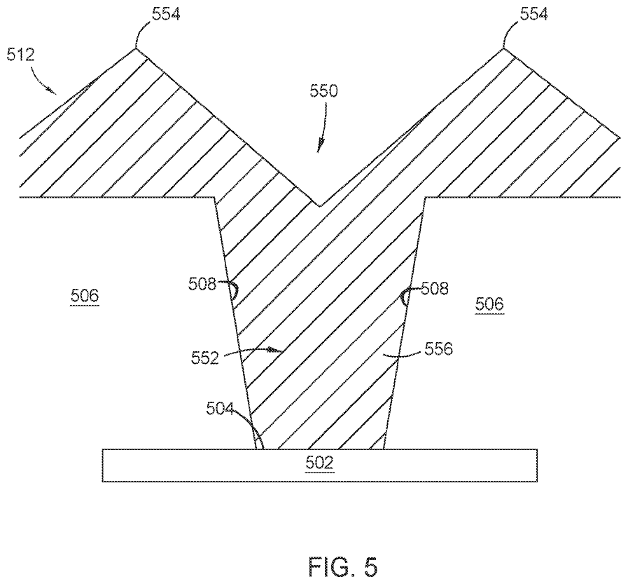

FIG. 4 is a flow diagram of a method 400 for forming an interconnection structure on a substrate, according to certain embodiments of the present disclosure. FIG. 5 depicts a schematic cross-sectional view of an embodiment of an interconnection structure formed according to the method 400 of FIG. 4. Method 400 describes forming an interconnection structure by depositing a gap fill material in a gap formed in a material layer on a semiconductor substrate. Although FIG. 5 is described in relation to the method 400, it will be appreciated that the structure disclosed in FIG. 4 are not limited to the method 400, but instead may stand alone as structures independent of the method 400. The interconnection structure may be any suitable structure formed on a substrate, such as an optical device, a channel structure, a fin structure, a gate structure, a contact structure, a front-end structure, a back-end structure or any other suitable structure utilized to fabricate semiconductor devices and the like. Similarly, although the method 400 is described with reference to FIG. 5, it will be appreciated that the method 400 is not limited to the structures disclosed in FIG. 5 but instead may stand alone independent of the structures disclosed in FIG. 5.

In an embodiment, the method 400 begins at operation 402 by providing a substrate 502 having a gap 552 formed in a material layer 506 disposed over a top surface of the substrate 502. In one embodiment, the substrate 502 may be part of a surface, such as a bottom surface 504 shown in FIG. 5 and exposed by an opening 550 in the material layer 506 disposed over the substrate 502. As shown, the opening 550 of the gap 552 in the material layer 506 exposes both the bottom surface 504 and the sidewalls 508 in the material layer 506. Method 400 may be performed to fill the gap 552 in the material layer 506 on the substrate 502 to form an interconnection structure 556. In one embodiment, the substrate 502 may have a substantially planar surface, an uneven surface, or a substantially planar surface having the material layer 506 and the interconnection structure 556 formed thereon.

In some embodiments, as shown in FIG. 5, the gap 552 in the material layer 506 extends from the opening 550 at a top surface of the material layer 506 to the bottom surface 504 on the substrate 502. The gap 552 may have an aspect ratio greater than 0.4:1, such as 0.5:1, 0.6:1, 0.7:1, and more. The opening 550 in the gap 552 may be filled with gap fill material 512 with minimal defects, such as minimal voids, seems or gaps. In some embodiments, which may be combined with other embodiments described herein, the gap 552 may include trenches, vias, holes, apertures and the like on a substrate for an optical device.

In one embodiment, the substrate 502 shown in FIG. 5 includes the material layer 506 formed on the substrate 502 with the gap 552 disposed in the material layer 506. In other embodiments, the gap 552 may be formed in and directly extend into the substrate 502. The substrate 502 and/or the material layer 506 may be made of material such as crystalline silicon, silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire.

At operation 404, a deposition process is performed to deposit a portion of the gap fill material 512 in opening 550 of the substrate 502 to partially fill the gap 552. In one embodiment, operation 404 includes performing a physical vapor deposition process using a process chamber, for example the process chamber 100 depicted in FIG. 1, to deposit the gap fill material 512 into the opening 550 of gap 552 with minimal defects.

In one embodiment, the gap fill material 512 is a dielectric film layer formed from one or more of a silicon containing material, a carbon containing material, or other suitable materials such as niobium oxide (NbOx). Other suitable silicon containing materials include silicon, silicon oxide, silicon nitride, silicon oxynitride, and combinations thereof. Suitable carbon containing materials include silicon carbide, silicon oxycarbide, amorphous carbon or the like. In another embodiment, the gap fill material 512 is fabricated as a metal film layer formed from one or more of aluminum, titanium, titanium nitride (TiN), cobalt, nickel, tungsten, copper, manganese, and/or other suitable metal(s).

In one embodiment, the gap fill material 512 deposited by process chamber 100 in the gap 552 comprises niobium oxide. For example, during the PVD process at operation 404, an oxygen-containing reactive gas (e.g., O₂) and a sputter gas (e.g., Ar) can be provided to the processing volume 105 of process chamber 100. Power can be provided to the second target 106 from the DC power source 112 to ignite the plasma 198 in the processing volume 105. Once the plasma 198 is formed, the sputtering plasma 198 is delivered to the first and/or second targets 104, 106 to form an ionized species, the ionized species forming a gap fill material on the substrate. In some embodiments, the DC power from the DC power source 112 can be pulsed to generate the plasma 198. In one embodiment, DC power can be provided from the DC power source 112 to the second target 106 at a power level from about 500 W to about 1 kW and about 1 kW to about 10 kW. In one embodiment, the DC power source 112 provides about 5 kW. In alternative embodiments, higher DC powers may be applied if multiple generators are implemented.

In an embodiment, the second target 106 can be a niobium (Nb) target. During the PVD process in operation 404, the plasma 198 of the sputter gas (e.g., argon) can bombard the second target 106 causing niobium atoms of the second target 106 to be ejected from the second target 106. The DC power can be used to attract ions and or radicals of the sputter gas as well as electrons and sputter the material from the second target 106. In an embodiment, oxygen atoms react with the niobium atoms on the second target 106 and form as niobium oxide (NbOx). The niboium and oxygen atoms may then be ejected as NbOx from the second target 106 and deposited over the substrate, such as on the substrate 502 in process chamber 100.

At operation 406, the method 400 continues with performing an etch process to remove portions of the gap fill material deposited on the substrate in prior operation 404. Prior to operation 406, the substrate 502 may be transferred to another process chamber for performing operation 406. In an embodiment, the substrate 502 may be transferred to an etch chamber, for example the process chamber 200 depicted in FIG. 2 for performing the etch process of operation 406.

The etch process in operation 406 may be performed on the substrate 502 over the field of the opening 550 and on a top surface of the gap fill material 512 deposited on the substrate 502 in operation 404. The etch process in operation 406 may performed to remove gap fill material 512 deposited on upper portions of the gap 552 near the opening 550, such as deposits formed on the sidewalls 508 near the entry and opening 550 of the gap 552. The process chamber 200 may be used to remove portions of the deposited oxides from gap fill material 512 deposited on the sidewall and entry surfaces around the opening 550 in operation 404 to ensure the opening 550 remains open for subsequent deposition gap fill processes to completely fill the opening 550.

In an embodiment, the etch process by the process chamber 200 may be performed by supplying a processing gas mixture including an oxygen or nitrogen containing gas and/or an inert gas to the processing region 241. In one embodiment, the oxygen and/or nitrogen containing gas may be supplied in the processing gas mixture and the inert gas may optionally be supplied during the etch process. Suitable examples of the oxygen containing gas include O₂, CO₂, O₃ and the like. Suitable examples of nitrogen containing gas include N₂, N₂O, and the like. Suitable examples of inert gases that may be supplied into the processing gas mixture include Ar, He, Ne, Kr, Xe and the like. In certain embodiments, the processing gas mixture can include pure O₂, pure N₂, an Ar and O₂ mixture, an Ar and N₂ mixture, or pure Ar.

While supplying the processing gas mixture, the substrate support temperature may be controlled to maintain the substrate 502 at a temperature greater than 250 degrees Celsius, such as greater than 300 degrees Celsius, and for example between 300 degrees Celsius and about 600 degrees Celsius. It is believed that the relatively higher substrate temperature control during the etch process may assist removing excess deposited oxides from the substrate surface. However, in other embodiments, lower temperatures may be used. The processing gas mixture is supplied through the chamber plasma region 221 into the substrate processing region 241 to form the remote plasma source in the chamber plasma region 221 from the processing gas mixture for removing the oxides. The amount of gases introduced into the process chamber 200 from the processing gas mixture may be varied and adjusted to accommodate, for example, the thickness of the oxide to be removed.

A remote plasma power is provided to form a plasma in the chamber plasma region 221 from the processing gas mixture supplied at operation 406. The plasma generated remotely in the chamber plasma region 221 during the etch process at operation 406 may have the etchants dissociated to form a relatively mild and gentle etchants, so as to slowly, gently and gradually etch the gap fill material 512, e.g., an isotropic etch process. The remote plasma process provides good control for the interface etching and promotes high etching selectivity.

In one embodiment, the etch process in operation 406 by the process chamber 200 may be performed via an Argon resputtering etch process in the process chamber 200. The processing gas mixture supplied to the process chamber 200 may be a resputter gas including argon (Ar), krypton (Kr), neon (Ne), or combination thereof. The processing gas mixture flow rate is between about 5 sccm and about 60 sccm, for a substrate having a 200 mm diameter. In an embodiment, the processing gas mixture flow rate is about 6 sccm. The resputtering of the surface of the layer of gap fill material 512 previously deposited in operation 404 using the processing gas mixture causes particles of the gap fill material 512 to be removed from the surface of the layer of deposited gap fill material 512.

In an embodiment, if operation 406 is performed with pure Ar gas such as the Argon resputtering etch process described herein, such etch process can cause high film loss and degradation of the deposited gap fill material 512. As such, after the etch process in operation 406, an optional operation 408 plasma treatment process may be performed in the same process chamber 200 to treat the etched surface of the gap fill material 512 and re-oxidize the surface of the etched gap fill material 512. The plasma treatment may re-form Nb—O bonds on the etched surface of the gap fill material 512 thereby increasing the oxygen concentration on the surface of the gap fill material 512. It is also believed that the plasma treatment process reduces surface roughness of the deposited gap fill material 512 by reducing impurities and densifying the gap fill material 512, thereby improving gap fill performance with no voids, seams, or weak spots.

Exemplary plasma forming gases that may be provided to the process chamber 200 for the plasma treatment process of operation 408 include oxygen (O₂), hydrogen (H₂), nitrogen (N₂), ammonia (NH₃), and combinations thereof. During the plasma treatment process, several process parameters may also be regulated. In one embodiment, the process pressure is controlled at between about 0.1 Torr and about 100 Torr (e.g., between about 0.1 Torr and about 80 Torr; between about 1 Torr and about 20 Torr or between about 7 Torr and about 30 Torr). In one implementation, the processing temperature is between about 100 degrees Celsius and about 900 degrees Celsius (e.g., between about 125 degrees Celsius and about 350 degrees Celsius, for example between about 200 degrees Celsius and about 300 degrees Celsius, such as between about 250 degrees Celsius and about 340 degrees Celsius). The RF power may be controlled at between about 100 Watts and about 800 Watts, for example, about 400 Watts. The plasma forming gas, such as O₂ gas, may be supplied at between about 1 sccm and about 1000 sccm, such as between about 5 sccm and about 200 sccm. The O₂ gas supplied from the substrate edge/substrate bottom may be controlled at between about 200 sccm and about 1000 sccm.

At operation 410, operations 404, 406, and 408 404 may be repeated to further deposit, etch, and optionally plasma treatment, respectively, the gap fill material 512 on the substrate 502. The number of cycles may be repeated as many times as needed to incrementally fill the gap 552 with the gap fill material 512 until complete filling of the opening 550 and the gap 552 is achieved. In some embodiments, between 2 cycles and 15 cycles of operations 404 and 406 may be performed for filling the gap 552.

In some embodiments, the repeating of the deposition and etch process in operation 410 may be performed until most of the gap is filled with the gap fill material 512. Thereafter, in operation 412, a final cycle of the deposition process is performed on the substrate 502 in process chamber 100 to form the last remaining portion of the gap fill material 512 and completely fill the opening 550. In an embodiment, a trench with an aspect ratio of 0.6:1 and having 113 nm height and 176 nm opening was completely filled with gap fill material 512 consisting of NbOx (with no voids, seams, or interface layers formed in the gap fill material) when three (3) cycles of (70 nm deposition and 20 nm etch) was performed followed by a final 50 nm deposition in operation 412.

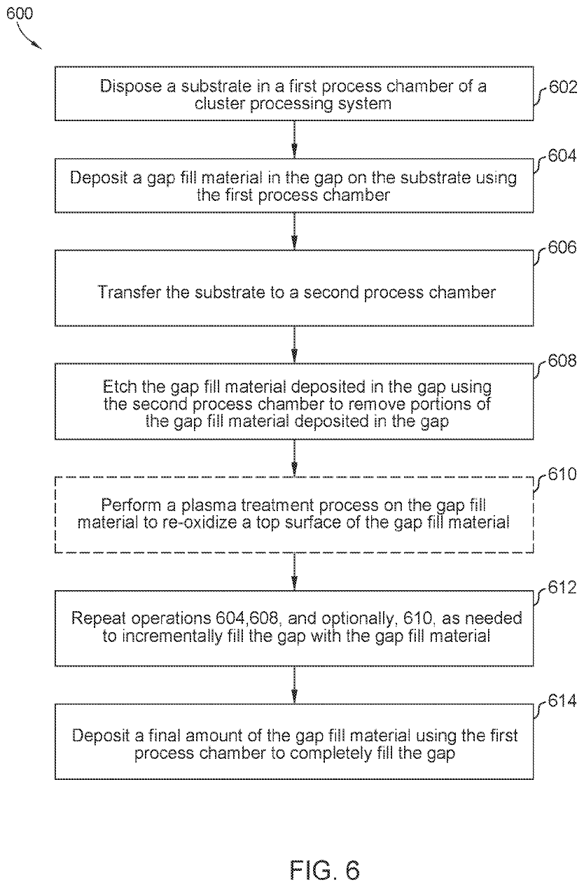

FIG. 6 is a flow diagram of an example method 600 for forming an interconnection structure using a cluster processing system, for example the cluster processing system 300 depicted in FIG. 3. The cluster processing system 300 may be configured with the process chamber 100 and the process chamber 200 described herein, for example, process chambers 350, 360 of the cluster processing system 300 may be configured as a physical vapor deposition process and a pre-cleaning chamber, respectively.

Operation 602 begins with disposing a substrate in a first process chamber of a cluster processing system, for example, the process chamber 350 of the cluster processing system 300 configured for performing a physical vapor deposition process. The substrate may be the substrate 502 as shown in FIG. 5 with gap 552 formed in the material layer 506 as described herein.

In operation 604, a deposition process is performed in process chamber 350 to deposit the gap fill material 512 in the gap 552 as discussed above with respect to operation 404 to partially fill the gap 552. In one embodiment, operation 604 includes performing a physical vapor deposition process using process chamber to deposit the gap fill material 512 into the opening 550 of gap 552 with minimal defects.

In operation 606, the substrate 502 having the gap 552 partially filled with the gap fill material 512 is transferred to a second process chamber, such as the process chamber 360 of the cluster processing system 300 configured as a pre-cleaning chamber. In an embodiment, transferring the substrate 502 between the process chambers 350, 360 within the same cluster processing system 300 enables performing operations 604 and 608 on the substrate 502 without breaking vacuum.

In operation 608, an etch process as described above with respect to operation 404 is performed using the process chamber 360 to remove portions of the gap fill material 512 previously deposited on the substrate 502 in operation 604. The etch process may be used to remove portions of deposited oxides from gap fill material 512 deposited on the sidewall 508 and entry surfaces around the opening 550 in operation 604 to ensure the opening 550 of gap 552 in the material layer 506 remains open for subsequent deposition gap fill processes to completely and seamlessly fill the gap 552.

After the etch process in operation 608 is complete, an optional operation 610 plasma treatment process may be performed using the same process chamber 360 to treat and re-oxidize the etched surface of the gap fill material 512. Optional operation 610 may be performed as described above for performing operation 408.

At operation 612, operations 606, 608, and 610 may be repeated to further deposit, etch, and optionally plasma treatment, respectively, the gap fill material 512 on the substrate 502, as needed to fill most of the gap 552 with gap fill material 512. The number of cycles may be repeated as many times as needed until complete filling of the opening 550 and the gap 552 is achieved. In some embodiments, the repeating of the deposition and etch process in operations 606 and 608 may be performed until most of the gap is filled with the gap fill material 512. Thereafter, in operation 614, a final deposition process is performed on the substrate 502 in process chamber 100 to form a final amount of the gap fill material 512 and completely fill the opening 550.

In an embodiment, a trench with an aspect ratio of 0.6:1 and having 110 nm height and 180 nm opening was completely filled with gap fill material 512 consisting of Aluminum (with no voids, seams, or interface layers) when eight (8) cycles of (40 nm Al deposition and 10 nm etch) was performed. In an embodiment, the gap fill material 512 comprising aluminum may be formed using processing chambers 350 and 360 described herein in the cluster processing system 300 with the performing of eight (8) mainframe cycles of Al deposition and etch in operations 604 and 608. For each mainframe cycle of Al deposition and etch, the substrate 502 may be transferred between process chambers 350 and 360 in cluster processing system 300 without being returned to the load lock chambers 322. Each cycle of the deposition process in operation 404 may approximately form a thickness, e.g., a portion, of between about 30 nm and about 70 nm of the gap fill material 512 on the substrate 502 depending on the size and depth of the gap to be filled and a desired field thickness. In each cycle, the deposition process may be performed for between about 20 seconds and about 600 seconds, for example, between about 30 seconds and 60 seconds. In each cycle of the etch process in operation 406, a portion of, e.g., between about 5 nm and about 10 nm, and between about 10 nm and about 30 nm, may be etched from the surface of the gap fill material 512. In each cycle, the etch process may be performed for between about 20 seconds and about 120 seconds.

Using aspects described herein, in an embodiment, it has been found that the cyclic process of PVD deposition and pre-cleaning etch can be used to completely fill high aspect ratio gaps (aspect ratios of at least 0.6:1) with gap fill materials comprising of dielectric layer materials, metals, metal oxides, metal nitrides, metal containing materials, and the like. In an embodiment, the cyclic deposition and pre-cleaning etch process may be performed on the cluster processing system 300 containing both the process chamber 100 and the process chamber 200 such that the method 400 disclosed herein may be performed by the cluster processing system 300.

Moreover, as the number of cycles of deposition and etch processes used increases, benefits of the present disclosure also include the cyclic process forming flat planar surfaces on the field surrounding the opening of the gaps as the opening and gap is being filled with the gap fill material.

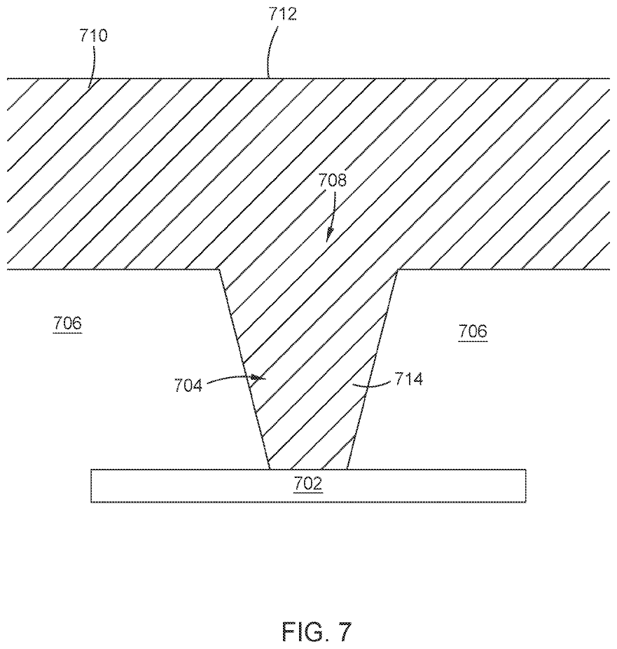

As shown in FIGS. 5 and 7, the process disclosed can also planarize the field surface surrounding the opening of the gap, thereby reducing the need for, and possibly even avoid altogether, any subsequent chemical mechanic polishing (CMP) process to prepare and flatten the surface for forming of subsequent optical structures. As discussed above, FIG. 5 depicts a cross-sectional view of an embodiment of the interconnection structure 556 formed in the gap 552 of the material layer 506. In an embodiment, the example gap fill material 512 completely filling the gap 552 shown in FIG. 5 may be formed from three (3) cycles of 70 nm deposition and 20 nm etch processes of NbOx, followed by a final 50 nm deposition of NbOx. As shown in FIG. 5, after the gap 552 is completely filled by the cyclic deposition and etch process, a plurality of peaks 554 are formed along a top surface of the gap fill material 512 over each of the structures in material layer 506 adjacent to the gap 552.

In another embodiment, FIG. 7 depicts a cross-sectional view of a gap fill material 710 formed in and over a trench 704 in a material layer 706 disposed on a substrate 702. The gap fill material 710 disposed over the material layer completely fills the trench 704 to form an interconnection structure 714. The gap fill material 710 disposed on the material layer 706 includes a flat and planar top surface 712. In an embodiment, the example gap fill material 710 may be formed from seven (7) cycles of 70 nm deposition and 20 nm etch processes of NbOx, followed by a final 50 nm deposition of NbOx. As shown in FIG. 7, the relative flat and planar top surface 712 formed from the cyclic gap fill process described herein forms the interconnection structure 714 that completely fills the trench 704. The methods described herein for depositing the gap fill material 710 may also prepare the top surface 712 of the gap fill material 710 for a subsequent layer or component formation on top of the gap fill material 710. As shown, the methods described herein may be performed to fill the trench 704 with the gap fill material 710 such that the top surface of the gap fill material 710 deposited over the trench 704 comprises a planarized flat surface thereafter. Advantages of the methods described herein therefore include avoiding the need for further processing of the top surface 712 of the gap fill material 710 to prepare or planarize the top surface 712 for further processing.

In an embodiment, the final deposition process performed over trench 704 may also be tailored and used to additionally fabricate gap fill material 710 to a desired thickness after trench 704 is filled. Methods 400 and 600 described herein therefore enables an additional thicker layer to be formed over the trench 704 after the trench 704 is filled without the need for additional intervening processes to planarize and prepare the top surface 712 of gap fill material 710. Accordingly, the disclosure described herein provides several benefits over conventional methods and systems.

While the foregoing is directed to embodiments of the present disclosure, other and further embodiments of the disclosure may be devised without departing from the basic scope thereof. The present disclosure also contemplates that one or more aspects of the embodiments described herein may be substituted in for one or more of the other aspects described. The scope of the disclosure is determined by the claims that follow.

What is claimed is:

1. A method for forming an optical device structure, comprising:
providing a substrate having a gap in a material layer disposed over a top surface of the substrate;
depositing a gap fill material over the material layer and in an opening of the gap in the material layer;
etching the gap fill material to remove portions of the gap fill material deposited in the gap; and
depositing more of the gap fill material in the opening of the gap to completely fill the gap.

2. The method in claim 1, further comprising cyclically depositing more of the gap fill material in the gap and etching the gap fill material to remove portions of the gap fill material deposited in the gap and near the opening of the gap to incrementally fill the gap with the gap fill material.

3. The method in claim 1, further comprising performing an O2 plasma treatment process on a top surface of the gap fill material deposited over the material layer and in the gap to re-oxidize the top surface of the gap fill material after portions of the gap fill material is etched.

4. The method in claim 4, wherein etching the gap fill material comprises using a pre-cleaning chamber and flowing a processing gas into the pre-cleaning chamber to ignite a plasma, wherein the processing gas comprises at least one of an argon, oxygen, or nitrogen containing gas.

5. The method in claim 1, wherein the gap fill material comprises material made of a dielectric film material, niobium oxide, metal, metal oxide, metal nitride, or a metal containing material.

6. The method in claim 1, wherein depositing the gap fill material comprises performing a physical vapor deposition process using a deposition chamber.

7. The method in claim 1, wherein the gap comprises an aspect ratio greater than about 0.4:1.

8. The method in claim 7, wherein the gap comprises an aspect ratio between about 0.5:1 and about 0.7:1.

9. The method in claim 1, further comprising depositing the gap fill material and etching portions of the gap fill material to planarize a top surface of the gap fill material.

10. A method for forming an optical device structure on a substrate, comprising:
disposing a substrate having a gap in a material layer disposed over the substrate into a first process chamber of a cluster processing system;
performing a deposition process using the first process chamber to deposit a gap fill material in an opening of the gap in the material layer;
transferring the substrate to a second process chamber of the cluster processing system;
performing an etch process using the second process chamber to remove portions of the gap fill material deposited in the gap on the substrate;
transferring the substrate to the first process chamber of the cluster processing system; and
performing a deposition process to deposit more of the gap fill material in the opening of the gap to completely fill the gap.

11. The method in claim 10, further comprising cyclically performing the deposition process in the first process chamber to deposit more of the gap fill material in the gap, and performing the etch process in the second process chamber to remove portions of the gap fill material deposited in the gap and near an opening of the gap to incrementally fill the gap with the gap fill material.

12. The method in claim 10, further comprising performing an O₂ plasma treatment process on a top surface of the gap fill material in the second process chamber after performing the etch process to re-oxidize the top surface of the gap fill material.

13. The method in claim 10, wherein the second process chamber comprises a pre-cleaning chamber, and performing the etch process comprises introducing a processing gas into the second process chamber to ignite a plasma, wherein the processing gas comprises at least one of an argon, oxygen, or nitrogen containing gas.

14. The method in claim 10, wherein the gap fill material comprises a material made of a dielectric film material, metal, metal oxide, metal nitride, or a metal containing material.

15. The method in claim 10, wherein the gap comprises an aspect ratio greater than 0.4:1.

16. The method in claim 10, further comprising depositing the gap fill material and etching portions of the gap fill material to planarize a top surface of the gap fill material.

17. An optical device structure, comprising:
a material layer disposed over a substrate, the material layer having a gap formed therein extending from a top surface of the material layer towards the substrate;
a gap fill material disposed over the material layer and in the gap, the gap fill material completely filling the gap to form an interconnection structure in the material layer, wherein the interconnection structure is formed in the material layer by:
depositing the gap fill material over the material layer and in the gap to partially fill the gap;
etching the gap fill material to remove portions of the gap fill material deposited in the gap;
continuing to cyclically deposit more of the gap fill material in the gap and etch portions of the gap fill material deposited in the gap to incrementally fill the gap with the gap fill material; and
depositing more of the gap fill material in the gap to completely fill the gap.

18. The optical device structure of claim 17, wherein the gap in the material layer comprises an aspect ratio greater than about 0.4:1.

19. The optical device structure of claim 17, wherein the gap fill material comprises material made of a dielectric film material, niobium oxide, metal, metal oxide, metal nitride, or a metal containing material.

20. The optical device structure of claim 17, wherein a top surface of the gap fill material comprises a planarized flat surface, the planarized flat surface formed by cyclically depositing the gap fill material and etching portions of the deposited gap fill material.
